(19) United States
(12) Patent Application Publication
(10) Pub. No.: US 2010/0116195 A1
(43) Pub. Date: May 13, 2010

(54) METHOD FOR GROWING SILICON SINGLE CRYSTAL

(75) Inventors: Ryoji Hoshi, Nishishirakawa (JP); Susumu Sonokawa, Nishishirakawa (JP)

Correspondence Address: OLIFF & BERRIDGE, PLC, P.O. BOX 320850, ALEXANDRIA, VA, 22320-4850, US

(73) Assignee: SHIN-ETSU HANDOTAI CO., LTD., Tokyo (JP)

(21) Appl. No.: 12/450,807

(22) PCT Filed: Apr. 18, 2008
(86) PCT No.: PCT/JP2008/001029

§ 371 Date: Oct. 14, 2009

(30) Foreign Application Priority Data
May 30, 2007 (JP) 2007-142988

(51) Int. Cl. C30B 15/00

(52) U.S. Cl. 117/21

(57) ABSTRACT

The present invention provides a method for growing a carbon-doped silicon single crystal that grows a silicon single crystal from a raw material melt in a crucible having carbon added therein by the Czochralski method, wherein an extruded material or a molded material is used as a dopant for adding the carbon to a raw material in the crucible. As a result, there can be provided the method for growing a carbon-doped silicon single crystal, by which the carbon can be easily doped in the silicon single crystal at low cost and a carbon concentration in the silicon single crystal can be accurately controlled in a silicon single crystal pulling up process by the Czochralski method.

### TECHNICAL FIELD

The present invention relates to a method for growing a silicon single crystal that slices out a silicon wafer used as a substrate for a semiconductor device such as memory or CPU, and more particularly to a method for growing a silicon single crystal that dopes carbon to control a BMD density for gettering crystal defects and impurities utilized in a most advanced field.

### BACKGROUND ART

A silicon single crystal from which a silicon wafer used as a substrate for a semiconductor device such as memory or CPU is sliced out is mainly produced by the Czochralski method (which will be referred to as the CZ method hereinafter).

A silicon single crystal produced by the CZ method contains oxygen atoms, and silicon atoms and the oxygen atoms are coupled with each other to form oxide precipitates (Bulk Micro Defects; which will be referred to as BMD hereinafter) when a silicon wafer sliced out from the silicon single crystal is used to fabricate a device. It is known that the BMD has an IG (Intrinsic Gettering) capability for capturing contaminating atoms of, e.g., a heavy metal in the wafer to improve device characteristic, and a device with higher performance can be obtained as the BMD density a bulk of the wafer increases. That is, a large quantity of BMD formed in the wafer leads to realization of high performance of a device.

Further, it is known that a quantity of BMD formed in the silicon wafer is dependent on an oxygen concentration in the silicon single crystal, a thermal history received during or after pulling up the silicon single crystal, a carbon concentration in the silicon single crystal, and others.

However, a quantity of BMD can be increased by raising an oxygen concentration but, on the other hand, there is a problem that OSF (Oxidation-induced Stacking Faults), which adversely affect a device, are apt to occur. When such OSF are present in a device active region on a silicon wafer, they become a factor of failures such as an increase in leakage current. Therefore, a silicon single crystal wafer that has an excellent IG capability and a reduced OSF density is demanded.

Intentionally doping carbon in the silicon single crystal to suppress OSF is known with respect to such a demand. That is because a crystal lattice of the carbon is smaller than an Si crystal lattice, a produced damage is absorbed, and precipitation of interstitial Si can be suppressed even though oxygen is present in the wafer. Further, when the carbon is doped, micro defects can be generated in an inner portion apart from an active region near a wafer surface, thereby improving the IG capability. Therefore, in recent years, to provide the sufficient IG capability while controlling the OSF in the silicon wafer, intentionally doping the carbon to produce the silicon single crystal has been carried out.

As a method for doping the carbon in a single crystal, gas doping (see Japanese Patent Application Laid-open No. H11-302099), a high-purity carbon powder (see Japanese Patent Application Laid-open No. 2002-293691), a carbon agglomeration (see Japanese Patent Application Laid-open No. 2003-146796), and others have been suggested. However, there are problems, e.g., remelting is impossible when a crystal is disordered in case of the gas doping, the high-purity carbon powder scatters due to, e.g., an introduced gas at the time of melting a raw material in case of the high-purity carbon powder, and carbon is hard to be dissolved and a crystal during growth is disordered in case of the carbon agglomeration.

As means that can solve such problems, Japanese patent Application Laid-open No. H11-312683 suggests a polycrystalline silicon container having a carbon powder accommodated therein, a silicon wafer containing carbon subjected to vapor phase film formation, a silicon wafer coated with an organic solvent containing carbon grains and baked, or a method for doping carbon in a silicon single crystal by putting polycrystalline silicon containing a predetermined amount of carbon into a crucible. Using these methods enables solving the above-described problems. However, these methods involve processing of polycrystalline silicon, a heat treatment for a doping wafer, and so on. Consequently, a preparation of a carbon dopant is not easy. Furthermore, there is a possibility of contamination of an impurity in the processing for adjusting the dopant or the wafer heat treatment.

Moreover, as means that can solve the above-described problems, Japanese Patent Application Laid-open No. 2005-320203 suggests a method for sandwiching a carbon powder between wafers. However, according to this method, doping can be performed at the beginning, but a carbon concentration cannot be changed. Additionally, when pulling up a plurality of single crystals from a single crucible, this method has a problem that a dopant cannot be added when pulling up the second or subsequent crystals.

### DISCLOSURE OF INVENTION

In view of the above-described problems, it is an object of the present invention to provide a method for growing a carbon-doped silicon single crystal, by which carbon can be readily doped in the silicon single crystal at low cost, the silicon single crystal can be made to be dislocation-free without problem, and a carbon concentration in the silicon single crystal can be accurately controlled. Further, it is also an object of providing a method for growing a carbon-doped silicon single crystal, by which additional doping of carbon, which is difficult in the conventional technology, can be easily carried out.

To achieve the objects, the present invention provides a method for growing a carbon-doped silicon single crystal that grows a silicon single crystal from a raw material melt in a crucible having carbon added therein by the Czochralski method, wherein an extruded material or a molded material is used as a dopant for adding the carbon to a raw material in the crucible.

When the extruded material and the molded material having the anisotropy is used as the dopant for adding the carbon in the raw material in the crucible to grow the carbon-doped silicon single crystal in this manner, the carbon in the silicon single crystal can be easily doped at low cost without adversely affecting single-crystallization of the crystal to grow.

In this case, it is preferable that the dopant consisting of the extruded material or the molded material is obtained by crushing an extruded material or a molded material to grains.

Since the extruded material and the molded material are relatively friable, it can be easily granulated, and a doping amount can be more accurately controlled to dope the carbon in the silicon single crystal and doping can be easily effected at low cost when the material obtained by crushing the extruded material or the molded material to grains is used as the dopant to grow the carbon-doped silicon single crystal. In this case, a size of the dopant is not restricted in particular, but setting the size to 0.1 to 30 mm is preferable.

Furthermore, it is preferable that the dopant is put into the crucible together with a silicon raw material, and then the raw material is melted to grow the single crystal.

When the dopant formed of, e.g., the crushed extruded material or molded material is put into the crucible together with the silicon raw material and then the raw material is melted to grow the single crystal in this manner, the carbon can be easily doped in the silicon single crystal at low cost, thereby obtaining the dislocation-free carbon-doped silicon single crystal. Moreover, when the dopant of the extruded material or the molded material formed with grains, weighing a desired amount can be facilitated, and hence controlling a carbon concentration in the raw material melt to a desired concentration can be also facilitated.

Additionally, the dopant can be put into the crucible containing a silicon raw material or the melt from the upper side, and then the single crystal can be grown.

When the dopant formed of, e.g., the crushed extruded material or molded material is put into the crucible containing a silicon raw material or the melt from the upper side and then the single crystal is grown in this manner, a dopant can be added at the time of pulling up the second or subsequent single crystals in case of pulling up the plurality of single crystals from the single crucible. Such additional doping is very difficult in the conventional technology, and the present invention is effective.

There can be provided the method for growing a carbon-doped silicon single crystal according to the present invention, by which the carbon can be easily doped in the silicon single crystal at low cost, the silicon single crystal can be made to be dislocation-free without problem, and the carbon concentration in the silicon single crystal can be accurately controlled when growing the silicon single crystal from the raw material melt in the crucible having the carbon added therein by the Czochralski method. Furthermore, using the present invention enables adding the dopant, the excellent controllability over the carbon concentration can be provided, and the present invention can be very easily carried out at low cost.

### BRIEF DESCRIPTION OF DRAWINGS

FIG. 1 is a schematic view of a silicon single crystal pulling up apparatus in the present invention;

FIG. 2 is a view schematically showing a state where carbon grains are fed in a crucible;

FIG. 3 is a view schematically showing a state where carbon grains are put into the crucible;

FIG. 4 is a graph in which each calculated value of a carbon concentration in a silicon single crystal grown in Example 1 is compared with each actual value of the same; and

FIG. 5 is a graph in which each calculated value of a carbon concentration in a silicon single crystal grown in Example 2 is compared with each actual value of the same.

### BEST MODE(S) FOR CARRYING OUT THE INVENTION

As explained above, the conventional technology has problems, e.g., a difficulty in remelting, scatter of the high-purity carbon powder, disorder of a crystal during growth, a difficulty in preparation of a carbon dopant, a possibility of impurity contamination, and others. Further, a carbon concentration is hard to be changed. Consequently, there occurs a problem that a dopant cannot be added at the time of pulling up the second or subsequent crystals when a plurality of single crystals are pulled up from a single crucible.

Here, as a carbon material used as the dopant, a CIP (isotropic) formed material that is extensively industrially used in the conventional semiconductor industry is adopted. The CIP formed material is obtained by solidifying finely ground raw material at a hydrostatic pressure, and hence it has dense and homogeneous tissues, but it has a problem that the CIP formed material is hard to react in a silicon melt and cannot be readily melted because it is dense.

In general, a graphite material is formed through kneading, forming, sintering, and graphitization after grinding a raw material, and it is classified into three types, i.e., the CIP (isotropic) formed material, an extruded material, and a molded material depending on a difference in forming process. The CIP formed material of these materials has dense and homogeneous tissues since a finely ground raw material is solidified at a hydrostatic pressure, and it is extensively industrially used in the semiconductor industry. However, the CIP formed material has the problem that it is hard to react in a silicon melt and cannot be easily melted since it is dense.

On the other hand, the extruded material and the molded material which are the graphite materials like the CIP (isotropic) formed material have anisotropy, and they have relatively large constituent grains and a low degree of hardness. Furthermore, these materials are porous as compared with the CIP formed material. Thus, the present inventors have considered that the extruded material and the molded material have high reactive properties with respect to silicon, and actively conducted experiments and examinations. As a result, the inventors have discovered that the extruded material and the molded material can be very easily melted in a silicon melt.

Moreover, the present inventors have revealed that carbon can be easily doped in a silicon single crystal at low cost, the silicon single crystal can be made to be dislocation-free without problem, and a carbon concentration in the silicon single crystal can be accurately controlled by using the extruded material or the molded material as a dopant, putting the dopant into a crucible together with a silicon raw material, and then melting the raw material to grow the single crystal. Furthermore, When the dopant is put into the crucible containing a silicon raw material or the melt from the upper side and then the single crystal is grown, additional doping that is very difficult in the conventional technology can be carried out at the time of pulling up the second or subsequent single crystals in case of pulling up the plurality of single crystals from the single crucible.

An embodiment according to the present invention will now be specifically explained hereinafter, but the present invention is not restricted thereto.

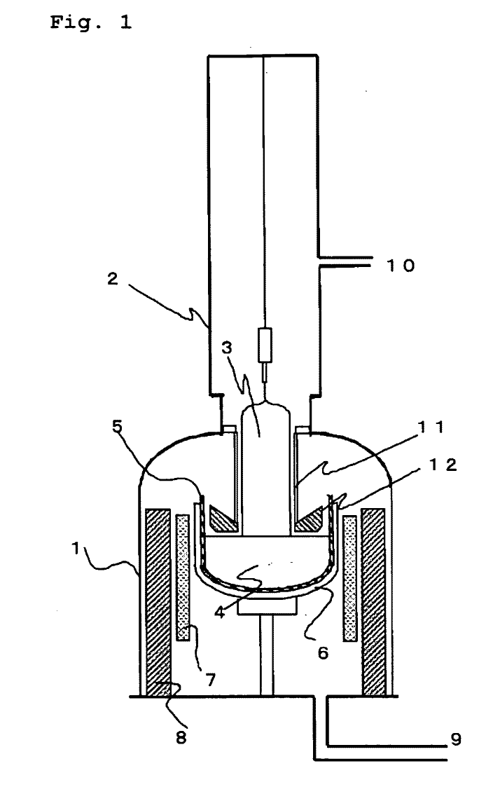

FIG. 1 shows an example of a single-crystal pulling up apparatus by the Czochralski method (the CZ method) that is used when carrying out a method for manufacturing a carbon-doped silicon single crystal according to the present invention. In a main chamber 1 of the single-crystal pulling up apparatus, a quartz crucible 5 which contains a melted raw material melt 4 and a graphite crucible 6 which supports the quartz crucible 5 are provided.

Polycrystalline silicon as a raw material of a carbon-doped silicon single crystal and a carbon dopant according to the present invention are charged into the quartz crucible. The carbon dopant used in the present invention is an extruded material or a molded material. As explained above, since the extruded material and the molded material have excellent reaction properties with respect to silicon and can be readily dissolved, a size of the dopant to be put into the crucible is not restricted in particular, but a size of 0.1 to 30 mm is preferable because of aspects of concentration controllability and operability. The quartz crucible 5 is provided in a furnace of such a single-crystal pulling up apparatus as shown in FIG. 1, and the CZ method is used to grow a crystal. According to the CZ method, the crucible (5 and 6) charged with the melt and a heater 7 arranged to surround the crucible are adopted. A seed crystal is subjected to immersion in the crucible, and then a rod-like single crystal 3 is pulled up from the melt. The crucible can be moved up and down in an axial direction of crystal growth, and the crucible is moved up so as to compensate a liquid level of the melt, which has been reduced because of crystallization during crystal growth. As a result, a height of the liquid level of the melt can be always maintained constant. It is to be note that an insulating material 8 provided outside the heater 7 to protect the chamber, and a gas flow-guide cylinder 11 and a heat insulating component 12 may be provided to facilitate cooling the crystal.

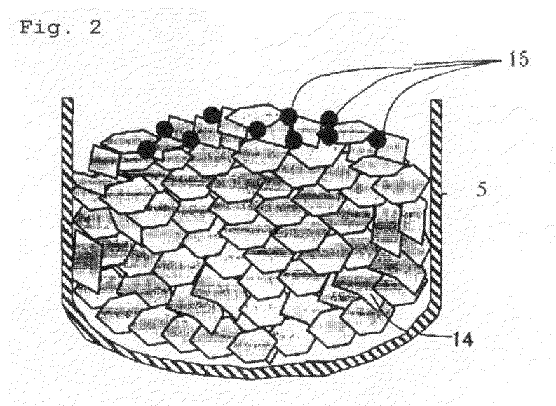

In this case, as the carbon dopant that is added in the crucible, for example, as shown in FIG. 2, it is preferable to charge granulated and purified carbon grains 15 into the quartz crucible 5 together with a polycrystalline silicon raw material 14.

Moreover, after charging the raw material in the quartz crucible 5, a vacuum pump (not shown) is operated to flow an Ar gas from a gas inlet 10 formed in the pulling up chamber 2 while performing exhaust from a gas outlet 9, thereby substituting the internal atmosphere with an Ar atmosphere.

Then, the graphite crucible 6 is heated by the heater 7 arranged to surround this crucible so that the raw material is melted to obtain a raw material melt 4. At this time, the carbon grains 15 as the dopant are melted in the melt 4 to add carbon. Since the carbon grains 15 are very easily melted, they are rapidly melted and blended in the raw material melt 4. When a grain diameter is set to, e.g., 0.1 to 30 mm, the carbon grains 15 can be melted in the raw material melt without being scattered due to the Ar gas. Since the carbon is not lost during melting as explained above, a carbon concentration in the raw material melt 4 can be accurately controlled to a desired concentration.

After the raw material and the dopant are melted, a seed crystal is immersed in the raw material melt 4, and the seed crystal is pulled up while being rotated, thereby growing a rod-like silicon single crystal 3. In this manner, a silicon single crystal having the carbon doped therein at the desired concentration is produced.

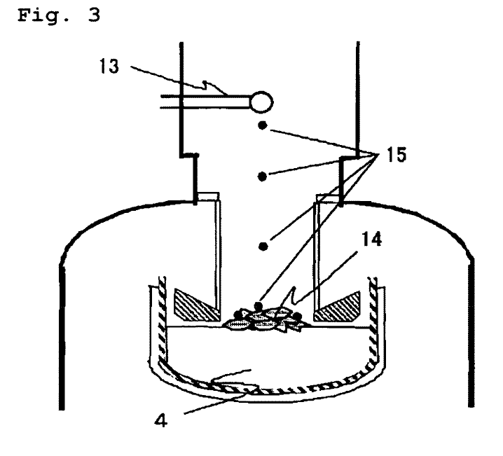

Additionally, as shown in FIG. 3, a desired quantity of the carbon grains 15 as the dopant can be put into the crucible from an input member 13 during or after melting of the raw material. According to this method, for example, when a plurality of single crystal ingots are grown in the single crucible, when an additional raw material must be put into the crucible after growing the first ingot, the dopant can be put into the crucible from the upper side together with the additional material or after adding the raw material.

The present invention will now be more specifically explained hereinafter with reference to examples thereof, but the present invention is not restricted thereto.

### EXAMPLE 1

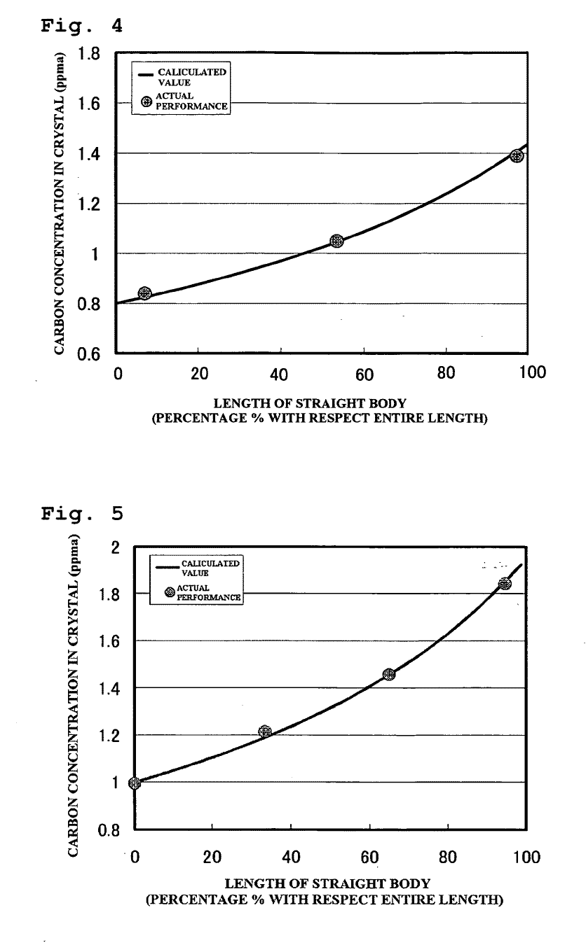

A quartz crucible having a diameter of 22 inches (550 mm) was provided in a furnace of a single-crystal pulling up apparatus to grow a silicon single crystal having a diameter of 8 inches (200 mm) by using the CZ method. According to the CZ method explained above, a polycrystalline silicon raw material and carbon grains were prepared, and the carbon grains were put into the quartz crucible together with the polycrystalline silicon raw material. At this moment, the carbon grains were set to have such a weight by which a carbon concentration in the silicon single crystal becomes 0.8 ppma in a straight body of 0 cm based on a segregation calculation. As the carbon grains, a material obtained by crushing a molded material to have a grain diameter of 3 to 10 mm and performing purification the same was used. The polycrystalline silicon raw material was melted together with the carbon grains, and then a single-crystal seed was immersed in a melt, thus growing a silicon single crystal having a diameter of 8 inches (200 mm). Wafer-like samples were sliced out from the straight body of the single-crystal silicon at several positions to measure carbon concentrations based on the FT-IR method. FIG. 4 shows a result.

### COMPARATIVE EXAMPLE 1

A silicon single crystal having a diameter of 8 inches (200 mm) was grown under the same conditions as Example 1 except that carbon grains were not put into a crucible. Wafer-like samples were sliced out at the same positions as those in Example 1, and carbon concentrations were measured based on the FT-IR method. As a result, at any positions, the carbon concentrations were equal to or below 0.03 ppma that is a measurement lower limit.

As shown in FIG. 4, the carbon concentrations equal to calculated values were obtained in Example 1. Further, a life time of the crystal was checked, and it was confirmed that the life time is substantially equal to that of a silicon single crystal having no carbon doped therein in Comparative Example 1, contamination of, e.g., a heavy metal did not occur, the dislocation of the crystal was not provided, and the silicon single crystal obtained in Example 1 was made to be dislocation-free without problem. Based on these facts, it was verified that doping the carbon grains enables taking carbon into the silicon crystal as intended.

### EXAMPLE 2

A crucible having a diameter of 18 inches (450 mm) was provided in a furnace of a single-crystal pulling up apparatus that is one size smaller than the single-crystal pulling up apparatus used in Example 1 to melt a silicon raw material, and a silicon single crystal having a diameter of 5 inches (125 mm) was pulled up. At this time, as shown in FIG. 3, a method of putting carbon grains into the crucible from the upper side was tried during melting of the polycrystalline silicon raw material. As the carbon grains, a material obtained by crushing a molded material to have a grain diameter of 3 to 10 mm and performing purification to the same was used. Further, a doping amount was set to an amount by which a carbon concentration in the silicon single crystal becomes 1.0 ppma when a straight body has a length of 0 cm. After the polycrystalline silicon raw material was completely melted, a single-crystal seed was immersed in a melt, thereby growing a silicon single crystal having a diameter of 5 inches (125 mm). Wafer-like samples were sliced out from the straight body of the silicon single crystal at several positions, and carbon concentrations were measured based on the FT-IR method. As a result, the carbon concentrations equal to calculated values were obtained as shown in FIG. 5. Moreover, it was confirmed that the obtained silicon single crystal was not contaminated with, e.g., a heavy metal and was made to be dislocation-free without problem.

### COMPARATIVE EXAMPLE 2

A silicon single crystal having a diameter of 5 inches (125 mm) was grown under the same conditions as those of Example 2 except that a material obtained by appropriately (approximately 1 to 3 mm) crushing a CIP formed material was used as a carbon dopant. After a silicon raw material was completely melted, a single-crystal seed was immersed in a melt to try to pull up a crystal, but the crystal was disordered, and obtaining a full-length single crystal was failed. Wafer-like samples were sliced out from a single-crystallized portion, and carbon concentrations were measured based on the FT-IR method. As a result, the carbon concentrations were lower than calculated values. It can be considered that this result was obtained because the CIP formed material has poor solubility and was not completely fused in the silicon melt, and an unfused part thereof remained in the melt as a foreign matter, thereby single-crystallization was obstructed.

It was revealed from the result of Example 2 that the carbon can be added during the process even though a carbon doping amount is not determined on the initial stage to then pull up a crystal like Example 1. Far example, when pulling up a plurality of single crystals from a single crucible, additional doping is required, but performing additional doping by using this method enables maintaining homogeneity of a carbon concentration. Additionally, the crystal was disorder and the full-length single crystal was not obtained in Comparative Example 2 where the CIP formed material was used as the dopant, whereas the silicon single crystal in which contamination of, e.g., a heavy metal did not occur and dislocation-free was obtained without problem since the molded material was used as the dopant in Example 2. Based on this fact, it was confirmed that using the molded material rather than the CIP formed material as the dopant is very effective when growing the carbon-doped silicon single crystal.

Based on the above-described results, it was revealed that using the method for growing a silicon single crystal according to the present invention enables easily doping carbon in a silicon single crystal at low cost, making the silicon single crystal to be dislocation-free without problem, and accurately controlling a carbon concentration in the silicon single crystal. Furthermore, additional doping of the carbon that is difficult in the conventional technology can be readily carried out.

It is to be noted that the present invention is not restricted to the foregoing embodiment. The foregoing embodiment is just an exemplification, and any examples, which have substantially the same configuration and demonstrate the same effects as those in the technical concept described in claims of the present invention are included in the technical scope of the present invention.

The above has explained the examples where the molded material is used as the dopant for adding the carbon, but the same results were obtained when an extruded material was utilized.

1. A method for growing a carbon-doped silicon single crystal that grows a silicon single crystal from a raw material melt in a crucible having carbon added therein by the Czochralski method, wherein an extruded material or a molded material is used as a dopant for adding the carbon to a raw material in the crucible.

2. The method for growing a carbon-doped silicon single crystal according to claim 1, wherein the dopant consisting of the extruded material or the molded material is obtained by crushing an extruded material or a molded material to grains.

3. The method for growing a carbon-doped silicon single crystal according to claim 1, wherein the dopant is put into the crucible together with a silicon raw material, and then the raw material is melted to grow the single crystal.

4. The method for growing a carbon-doped silicon single crystal according to claim 2, wherein the dopant is put into the crucible containing a silicon raw material or the melt from the upper side, and then the single crystal is grown.

5. The method for growing a carbon-doped silicon single crystal according to claim 1, wherein the dopant is put into the crucible containing a silicon raw material or the melt from the upper side, and then the single crystal is grown.

6. The method for growing a carbon-doped silicon single crystal according to claim 2, wherein the dopant is put into the crucible containing a silicon raw material or the melt from the upper side, and then the single crystal is grown.
